(19) United States
(12) Patent Application Publication
(10) Pub. No.: US 2005/0207122 A1
(43) Pub. Date: Sep. 22, 2005

(54) Heat dissipating device having an arcuate outer surface

(76) Inventor: Yung-Pin Kuo, Chang Hwa City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/862,387

(22) Filed: Jun. 8, 2004

(30) Foreign Application Priority Data
Mar. 17, 2004 (TW) 093204058

(51) Int. Cl. H05K 7/20

(52) U.S. Cl. 361/704

(57) ABSTRACT

A heat dissipating device includes an aluminum heat dissipating portion that has a connection part with an arcuate outer surface and an arcuate inner surface. A plurality of fins extend from the arcuate outer surface of the connection part by way of skiving and a cupper made base is connected to the arcuate inner surface of the connection part.

### FIELD OF THE INVENTION

The present invention relates to a heat dissipating device having an arcuate outer surface from which fins extend.

### BACKGROUND OF THE INVENTION

A conventional heat dissipating device generally uses aluminum which has better heat dissipation feature and the fins are made by way of extruding. However, the pitches between the fins and the thickness of the fins are limited so that the conventional heat dissipating device can only have less number of the fins. A fan is required to cooperate with the conventional heat dissipating device so as to increase the speed of the air flow through the fins. In order to reduce negative pressure of the air flow, the fins are orientated and arranged in a specific way and this needs a lot of work. Some manufacturers adhere the fins to the base of the heat dissipating device and the adhesive affects the heat conduction.

The present invention intends to provide a heat dissipating device that includes an aluminum made connection part and a plurality of fins extend from the connection part by way of skiving and the connection part is bent to be an arcuate piece so that the fins extend radially.

### SUMMARY OF THE INVENTION

The present invention relates to a heat dissipating device which comprises a heat dissipating portion having a connection part and a plurality of fins extend from an outer surface thereof by way skiving and the connection part is bent to be an arcuate piece so that the fins extend radially from the arcuate outer surface of the connection part. A base is connected to the arcuate inner surface of the connection part.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a first embodiment of the heat dissipating device of the present invention;

FIG. 2 shows the steps for making the heat dissipating device of the present invention as shown in FIG. 1;

FIG. 3 shows an exploded view of the base and the heat dissipating portion of the heat dissipating device of the present invention;

FIG. 4A is a cross sectional view of the heat dissipating device of the present invention;

FIG. 4B shows the base is put on a heat source and a fan is connected to a top of the heat dissipating device, the arrow heads shows the path of the heat flow;

FIG. 5A is a cross sectional view of a second embodiment of the heat dissipating device of the present invention;

FIG. 5B shows the base is put on a heat source and a fan is connected to a top of the heat dissipating device as shown in FIG. 5A, the arrow heads shows the path of the heat flow;

FIG. 6 shows the temperature illustrated by colored areas of the heat dissipating device of the present invention;

FIGS. 7A, 7B and 7C show third, fourth and fifth embodiments of the heat dissipating device of the present invention;

FIG. 8 shows that the heat dissipating device of the present invention is used in a personal computer with two fans are used to provide air flow.

### DETAILED DESCRIPTION OF THE PREFERRED EMBODIMENT

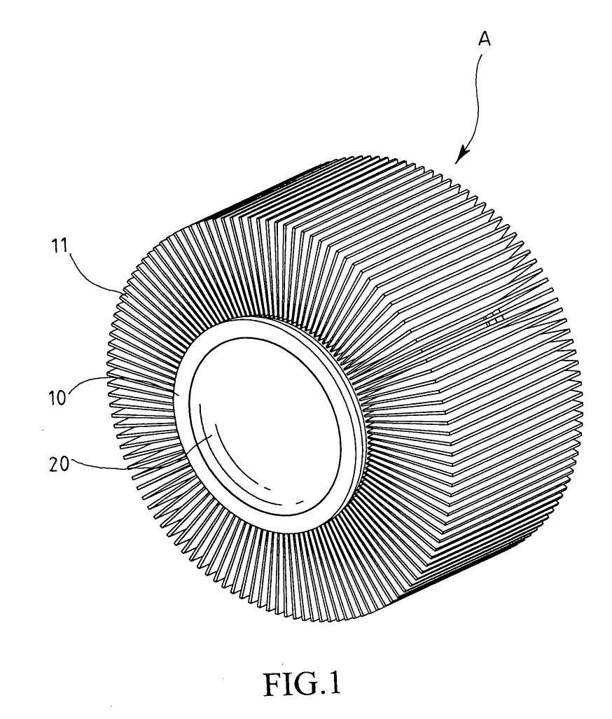

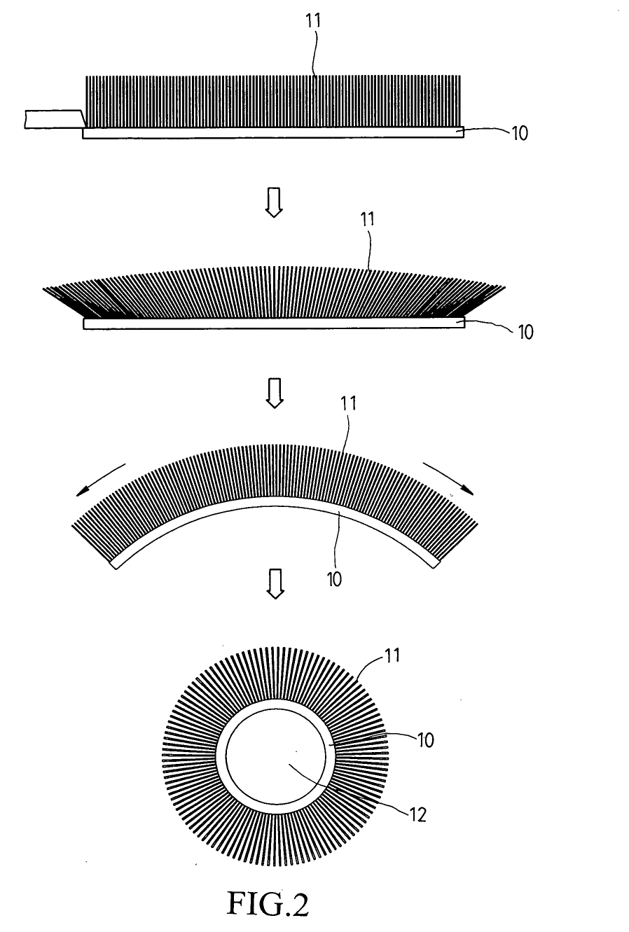

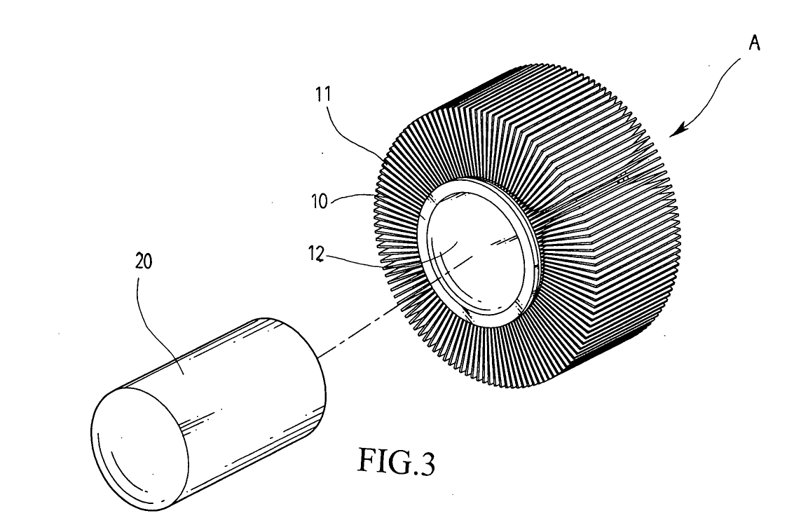

Referring to FIGS. 1 to 4, the heat dissipating device “A” of the present invention comprises a base 20 made of high heat conduction material such as cupper and is cooperated with a heat dissipating portion which includes a connection part 10 made of high heat dissipating material such as aluminum.

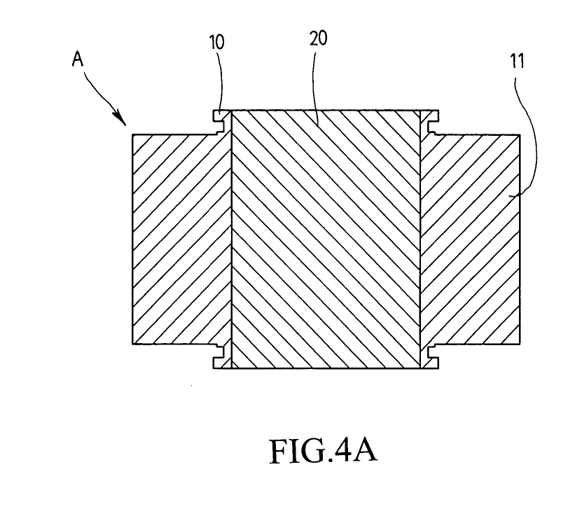

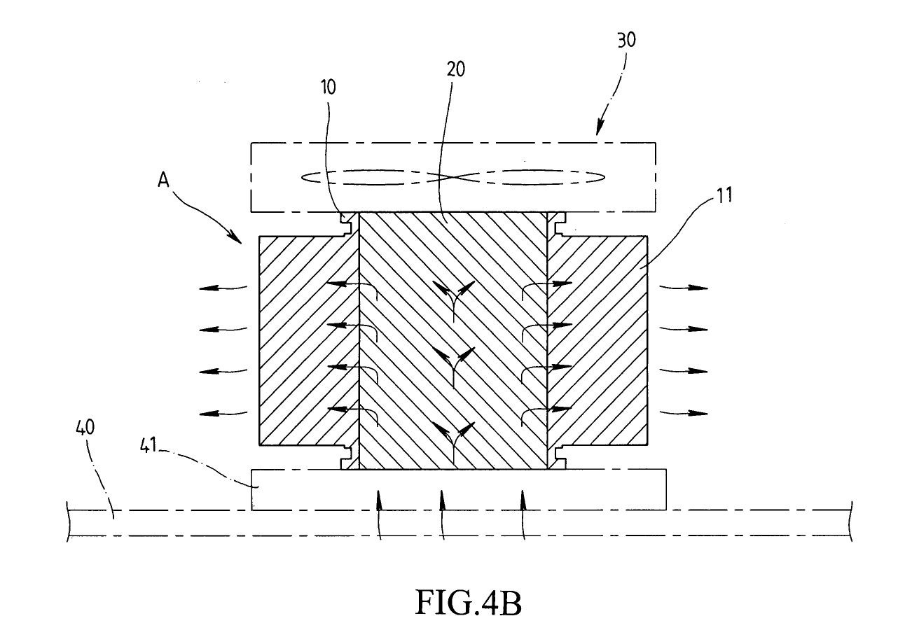

The connection part 10 is machined by way of skiving to have a plurality of fins 11 extending form a first side thereof and the connection part 10 is then bent to include an arcuate outer surface from which the fins 11 extend radially and an arcuate inner surface which is located in opposite to the arcuate outer surface. The fins 11 extend in a normal direction of the arcuate outer surface of the connection part 10. The arcuate inner surface is an enclosed circle and a cylindrical base 20 is received in the space 12 that is enclosed by the arcuate inner surface of the connection part 10. The base 20 is in contact with the arcuate inner surface of the connection part 10. As shown in FIG. 4B, the base 20 has its flat outer surface put on a heat source 41 of an electric part 40 and a fan 30 is connected to the other end of the base 20 so as to blow air through gaps between the fins 11. The arrow heads shows the path of the heat flow which goes away from the heat source 41.

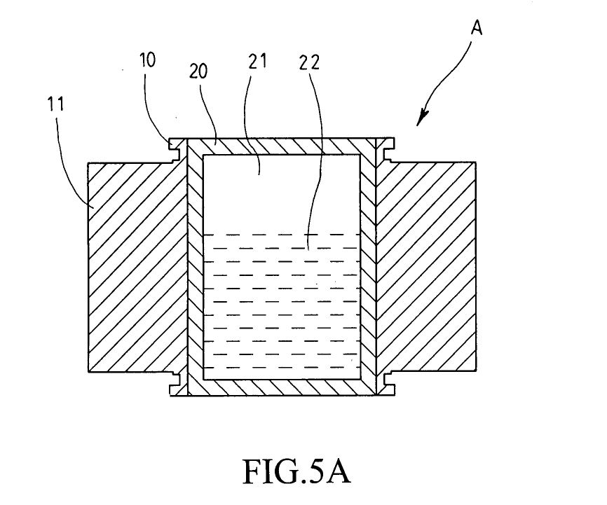

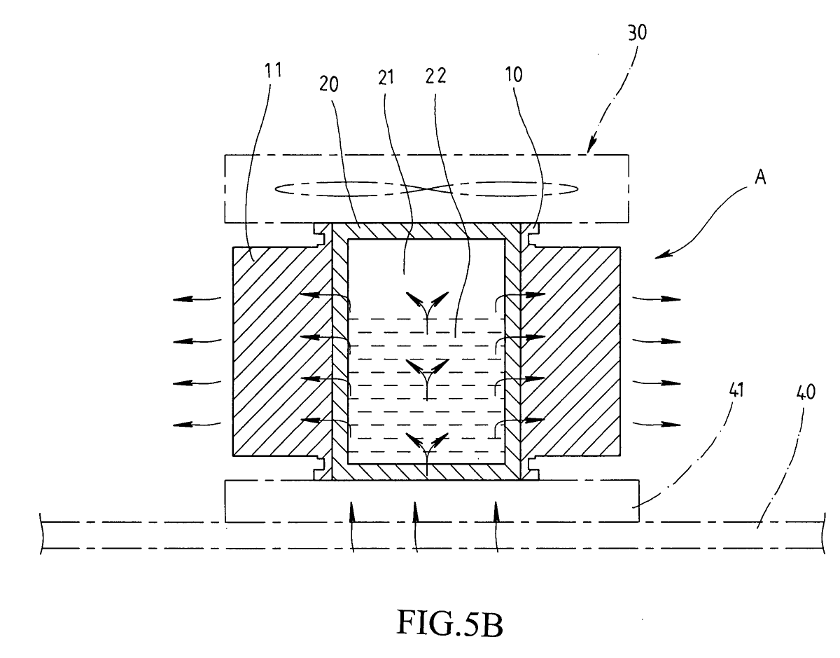

Referring to FIGS. 5A and 5B, the base 20 may have a hollow interior space 21 in which vaporable liquid 22 is filled. The vaporable liquid 22 can be water, carbinol, acetone, sodium or mercury, and is vaporized when absorbing heat from the heat source 41. The vapor moves toward the cool area at the other end of the base 20 and the heat is transferred to the fins 11 and radiates into air by the fan 30. The vapor is then cooled to be liquid again.

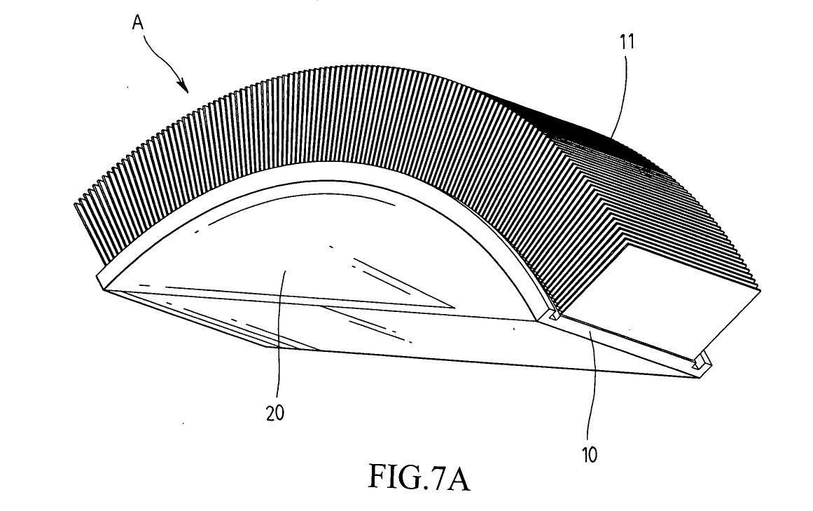

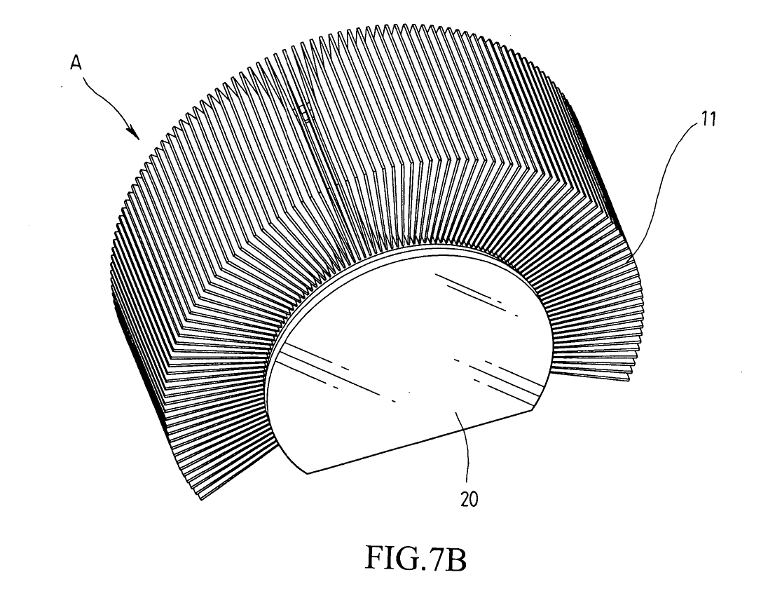

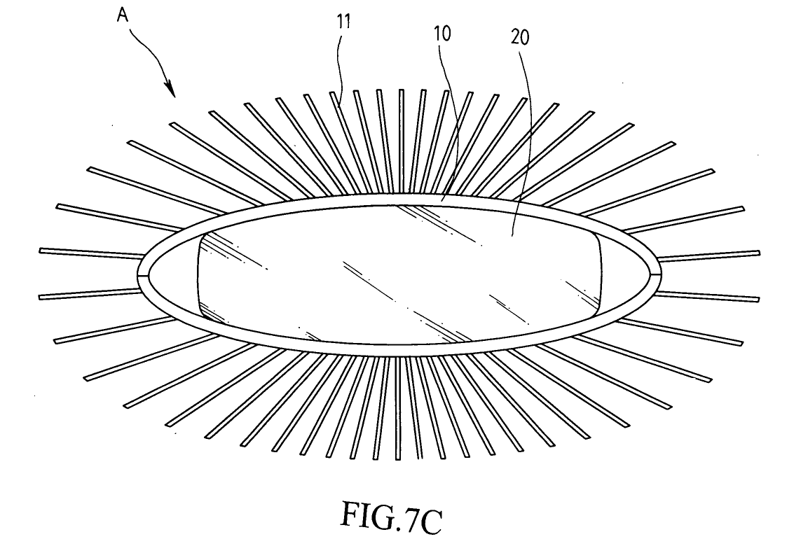

FIGS. 7A and 7B show that the arcuate inner surface of the connection part 10 is an arcuate section and the base 20 is matched with the arcuate inner surface. FIG. 7C shows that two connection parts 10 can be matched with each so as to form an enclosed oval space in which a base 20 is received.

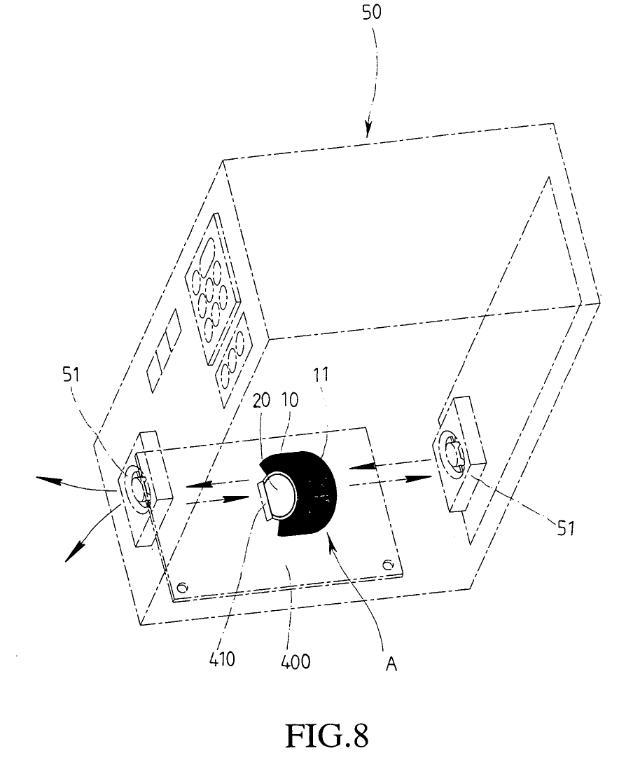

FIG. 8 shows that the heat dissipating device “A” of the present invention is used in a personal computer 50 and the base 20 is put on a CPU 410 on a circuit board 400. Two fans 51 are located at two opposite sidewalls of the casing of the computer 50 so as to generate air flow through the gaps between the fins 11 to remove the heat generated from the CPU 410.

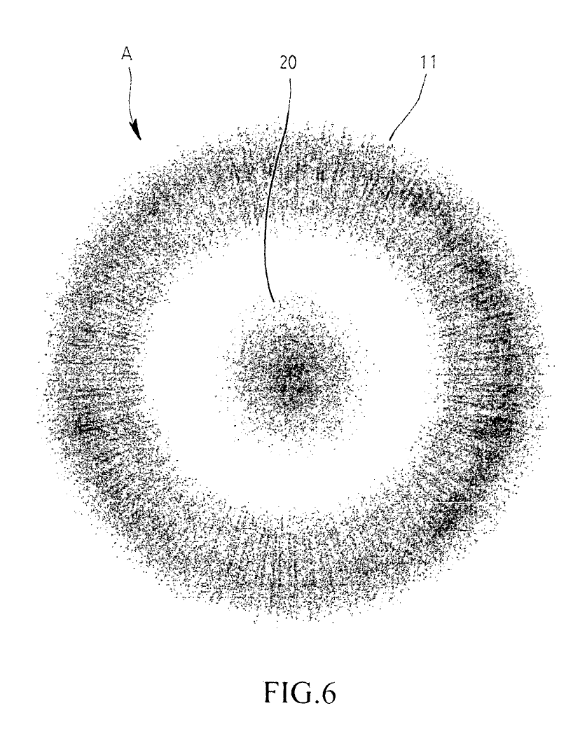

FIG. 6 shows that the base 20 is shown in red which is higher than 65.9 degrees Celsius and the distal ends of the fins 11 are shown in light blue which is lower than 42.7 degrees Celsius. This test result shows that the heat dissipating device “A” has satisfied function for removing heat from the heat source.

While we have shown and described the embodiment in accordance with the present invention, it should be clear to those skilled in the art that further embodiments may be made without departing from the scope of the present invention.

1. A heat dissipating device comprising:
a heat dissipating portion having a connection part which has an arcuate outer surface and an arcuate inner surface which is located in opposite to the arcuate outer surface, a plurality of fins extending from the arcuate outer surface of the connection part, and
a base connected to the arcuate inner surface of the connection part.

2. The device as claimed in claim 1, wherein the fins extend in a normal direction of the arcuate outer surface of the connection part.

3. The device as claimed in claim 1, wherein the arcuate inner surface is an enclosed circle.

4. The device as claimed in claim 1, wherein the base has at least one flat outer surface.

5. The device as claimed in claim 1, wherein the base has a hollow interior space in which vaporable liquid is filled.

6. The device as claimed in claim 5, wherein the vaporable liquid is water, carbinol, acetone, sodium or mercury.

7. The device as claimed in claim 1, wherein the base is made by cupper.

8. The device as claimed in claim 1, wherein the heat dissipating portion is made by aluminum.
